(19) United States
(12) Patent Application Publication
(10) Pub. No.: US 2026/0221190 A1
(43) Pub. Date: Jul. 30, 2026

(54) SEMICONDUCTOR MEMORY DEVICE AND METHOD OF CONTROLLING THE SAME

(71) Applicant: KIOXIA CORPORATION, Tokyo (JP)

(72) Inventors: Tatsuo OGURA, Yokkaichi (JP); Shunichi SENO, Yokkaichi (JP); Fumitaka ARAI, Yokkaichi (JP)

(73) Assignee: KIOXIA CORPORATION, Tokyo (JP)

(21) Appl. No.: 19/238,706

(22) Filed: Jun. 16, 2025

(30) Foreign Application Priority Data
Jan. 24, 2025 (JP) 2025-010567

(51) Int. Cl. G11C 16/10; G11C 5/06; G11C 16/04; G11C 16/24; G11C 16/26; G11C 16/32; H10B 43/10; H10B 43/27; H10B 43/35

(52) U.S. Cl. CPC G11C 16/10; G11C 5/063; G11C 16/0433; G11C 16/24; G11C 16/26; G11C 16/32; H10B 43/10; H10B 43/27; H10B 43/35

(57) ABSTRACT

A semiconductor memory device comprises: semiconductor layers stacked in a stacking direction and extending in a first direction; conductive layers connected to end portions of the semiconductor layers; via electrodes arranged along side surfaces of the semiconductor layers, and having diameters that increase from a first position to a second position in the stacking direction; and electric charge accumulating layers provided between the semiconductor layers and the via electrodes. At a program operation, in a state where conductive layers provided in a range from the first position to a third position in the stacking direction are applied with a first voltage or with a second voltage, and second conductive layers provided in a range from the second position to a fourth position in the stacking direction are applied with a third voltage or with a fourth voltage, one via electrode is applied with a program voltage.

### CROSS-REFERENCE TO RELATED APPLICATIONS

This application is based upon and claims the benefit of Japanese Patent Application No. 2025-010567, filed on Jan. 24, 2025, the entire contents of which are incorporated herein by reference.

### BACKGROUND

### Field

The present embodiments relate to semiconductor memory devices and methods of controlling the same.

### Description of the Related Art

There is known a semiconductor memory device comprising: a plurality of semiconductor layers stacked in a stacking direction and extending in a first direction intersecting the stacking direction; a plurality of via electrodes that are arranged in the first direction, extend in the stacking direction, and face the plurality of semiconductor layers; and a plurality of electric charge accumulating layers provided between the plurality of semiconductor layers and the plurality of via electrodes.

### BRIEF DESCRIPTION OF THE DRAWINGS

FIG. 1 is a schematic perspective view showing a part of a configuration of a semiconductor memory device according to a first embodiment;

FIG. 2 is a schematic circuit diagram showing a part of a configuration of a memory cell array layer L_{MCA};

FIG. 3 is a schematic plan view showing a part of a configuration of the memory cell array layer L_{MCA};

FIG. 4 is a schematic cross-sectional view showing a part of a configuration of the memory cell array layer L_{MCA};

FIGS. 5A and 5B are schematic diagrams for explaining threshold voltage of a memory cell MC stored with 3 bits of data;

FIG. 6 is a flowchart for explaining an overview of a write operation;

FIG. 7 is a schematic circuit diagram for explaining an overview of a program operation;

FIG. 8 is a schematic circuit diagram for explaining an overview of a verify operation;

FIG. 9 is a schematic cross-sectional view showing a part of a configuration of the semiconductor memory device according to the first embodiment;

FIG. 10 is a schematic circuit diagram for explaining a write operation according to the first embodiment;

FIG. 11 is a schematic waveform diagram for explaining one example of the write operation according to the first embodiment;

FIG. 12 is a schematic waveform diagram for explaining another example of the write operation according to the first embodiment;

FIG. 13 is a schematic histogram for explaining advantages of the write operation according to the first embodiment;

FIG. 14 is a schematic histogram for explaining advantages of the write operation according to the first embodiment;

FIG. 15 is a schematic circuit diagram showing a configuration example of a part of a peripheral circuit of the semiconductor memory device according to the first embodiment;

FIG. 16 is a schematic circuit diagram showing a configuration example of a part of the peripheral circuit of the semiconductor memory device according to the first embodiment; and

FIG. 17 is a schematic waveform diagram for explaining one example of a write operation according to a second embodiment.

### DETAILED DESCRIPTION

A semiconductor memory device according to one embodiment comprises: a plurality of semiconductor layers stacked in a stacking direction and extending in a first direction intersecting the stacking direction; a plurality of conductive layers which are stacked in the stacking direction correspondingly to the plurality of semiconductor layers, extend in a second direction intersecting the stacking direction and the first direction, and are connected to end portions in the first direction of the plurality of semiconductor layers; a plurality of via electrodes which are arranged in the first direction along side surfaces in the second direction of the plurality of semiconductor layers, extend in the stacking direction, face the plurality of semiconductor layers, and have diameters that increase from a first position to a second position in the stacking direction; and a plurality of electric charge accumulating layers provided between the plurality of semiconductor layers and the plurality of via electrodes. In this semiconductor memory device, at a first timing of a program operation causing an electric charge to be accumulated in a part of the plurality of electric charge accumulating layers, in a state where a plurality of first conductive layers provided in a range from the first position in the stacking direction to a third position between the first position and the second position in the stacking direction, of the plurality of conductive layers, have been applied with a first voltage or with a second voltage greater than the first voltage, and a plurality of second conductive layers provided in a range from the second position in the stacking direction to a fourth position between the second position and the third position in the stacking direction, of the plurality of conductive layers, have been applied with a third voltage greater than the first voltage and less than the second voltage, or with a fourth voltage greater than the third voltage, one of the plurality of via electrodes is applied with a first program voltage.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a first configuration is said to be “connected between” a second configuration and a third configuration, it will sometimes mean that the first configuration, the second configuration, and the third configuration are connected in series, and the second configuration is connected to the third configuration via the first configuration.

Moreover, in the present specification, when a circuit, or the like, is said to “make electrically conductive” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting the first direction along this certain plane will sometimes be referred to as a second direction, and a direction intersecting this certain plane will sometimes be referred to as a third direction. These first direction, second direction, and third direction may correspond to any of the X-direction, the Y-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

### First Embodiment

### Configuration

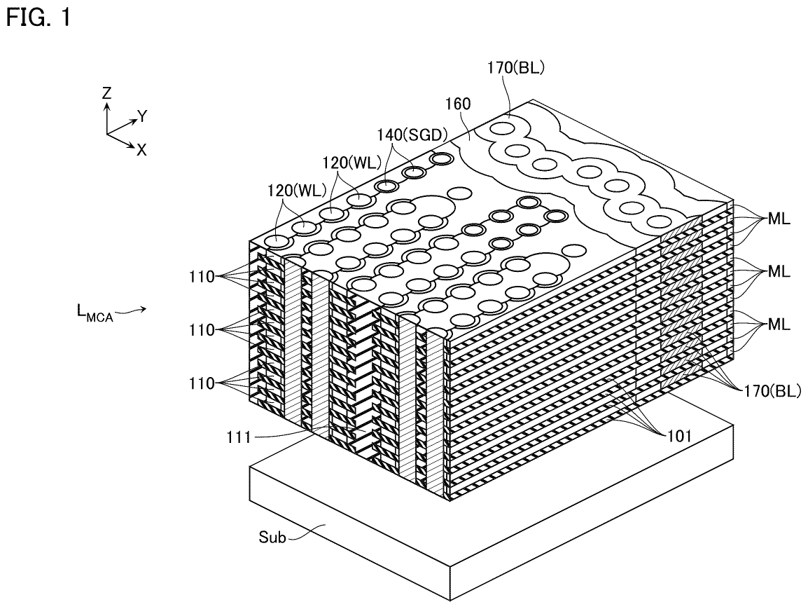

FIG. 1 is a schematic perspective view showing a part of a configuration of a semiconductor memory device according to a first embodiment. The semiconductor memory device according to the present embodiment comprises: a semiconductor substrate Sub; and a memory cell array layer L_{MCA} provided above the semiconductor substrate Sub.

The semiconductor substrate Sub includes the likes of silicon (Si) containing a P-type impurity such as boron (B), for example. An upper surface of the semiconductor substrate Sub is provided with a peripheral circuit for controlling configurations in the memory cell array layer L_{MCA}.

The memory cell array layer L_{MCA} comprises a plurality of memory layers ML and a plurality of insulating layers 101 that are stacked alternately in the Z-direction. The insulating layer 101 includes the likes of silicon oxide (SiO₂), for example.

### Configuration of Memory Cell Array Layer L_{MCA}

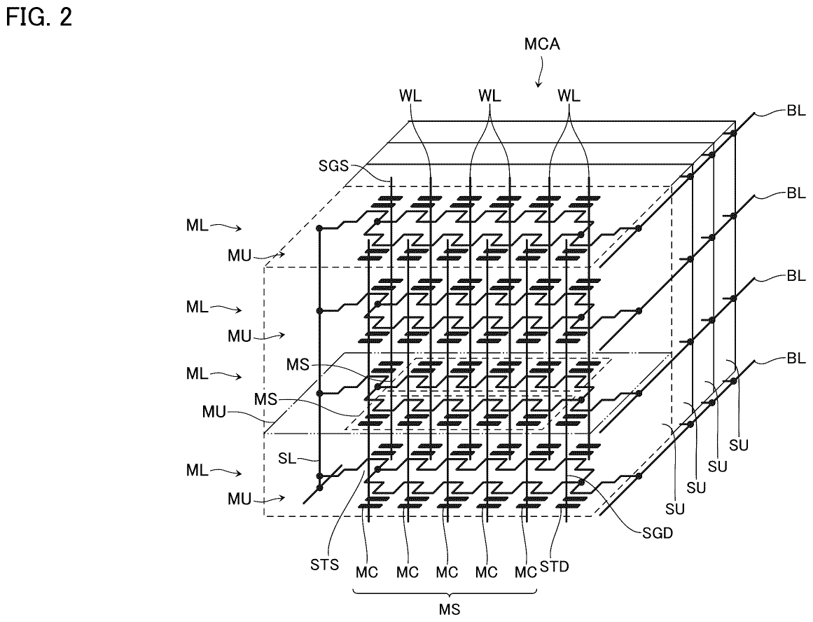

FIG. 2 is a schematic circuit diagram showing a part of a configuration of the memory cell array layer L_{MCA}.

The memory cell array layer L_{MCA} according to the present embodiment functions as a memory cell array MCA. The memory cell array MCA comprises a plurality of string units SU. The string units SU each comprise a plurality of memory units MU provided correspondingly to the plurality of memory layers ML. The plurality of memory units MU each comprise two memory strings MS. These two memory strings MS each comprise a plurality of memory cells MC (memory transistors) connected in series. One ends of these two memory strings MS are connected to a bit line BL via a common drain side select transistor STD. Moreover, the other ends of these two memory strings MS are connected to a source line SL via a common source side select transistor STS. Hereafter, the drain side select transistor STD and the source side select transistor STS will sometimes simply be referred to as select transistors STD, STS.

The memory cell MC is a field effect type transistor. The memory cell MC comprises a semiconductor layer, a gate insulating layer, and a gate electrode. The semiconductor layer functions as a channel region. The gate insulating layer includes an electric charge accumulating layer. Threshold voltage of the memory cell MC changes according to an amount of electric charge in the electric charge accumulating layer. The memory cell MC stores 1 bit or a plurality of bits of data. Note that the respective gate electrodes of the plurality of memory cells MC included in one memory unit MU are connected with word lines WL. These respective word lines WL are commonly connected to all of the memory units MU in the plurality of string units SU.

The select transistors STD, STS are each a field effect type transistor. The select transistors STD, STS each comprise a semiconductor layer, a gate insulating layer, and a gate electrode. The semiconductor layer functions as a channel region. The gate electrodes of the select transistors STD, STS are respectively connected with select gate lines SGD, SGS. The respective drain side select gate lines SGD are commonly connected to all of the memory units MU in their corresponding string units SU. The respective source side select gate lines SGS are commonly connected to all of the memory units MU in their corresponding string units SU.

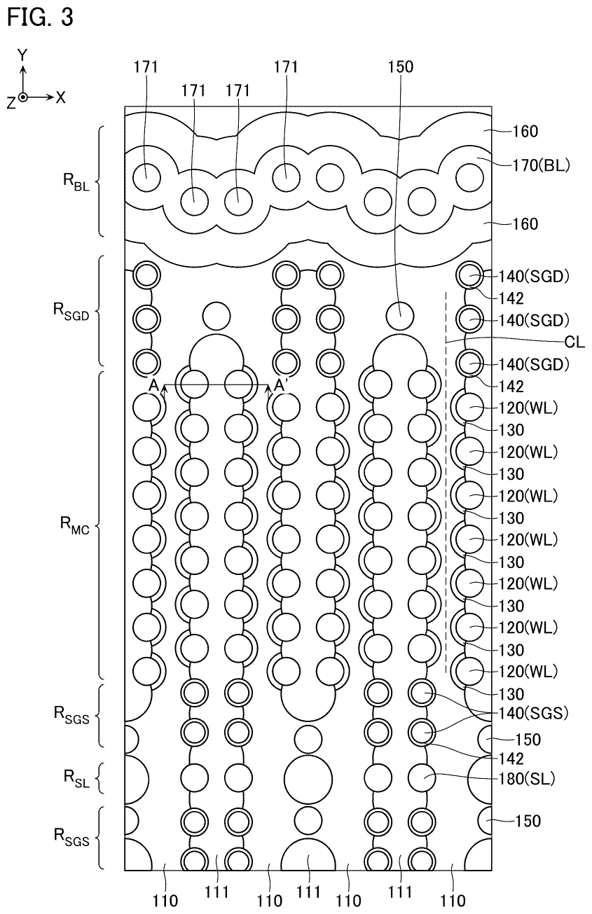

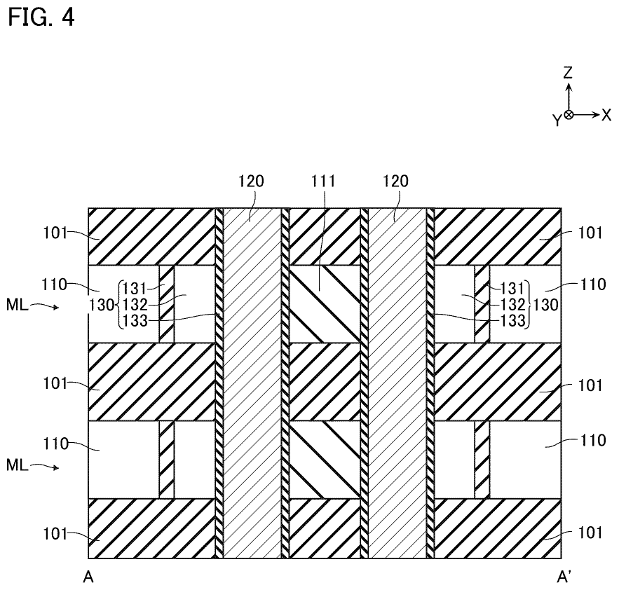

FIG. 3 is a schematic plan view showing a part of a configuration of the memory cell array layer L_{MCA}. FIG. 4 is a schematic cross-sectional view showing a part of a configuration of the memory cell array layer L_{MCA}. FIG. 4 shows a diagram in which the structure shown in FIG. 3 has been cut along the line A-A′ and viewed along a direction of the arrows.

As shown in FIG. 3, the memory cell array layer L_{MCA} comprises a bit line region R_{BL}, a select transistor region R_{SGD}, a memory cell region R_{MC}, a select transistor region R_{SGS}, and a source line region R_{SL} arranged in order in the Y-direction.

The memory layer ML comprises a plurality of semiconductor layers 110 arranged in the X-direction and extending in the Y-direction. These plurality of semiconductor layers 110 each extend in the Y-direction over the select transistor region R_{SGD}, memory cell region R_{MC}, select transistor region R_{SGS}, and source line region R_{SL}, and reach the bit line region R_{BL}. The semiconductor layer 110 functions as channel regions of the serially-connected plurality of memory cells MC (FIG. 2) and of the select transistors STD, STS connected to these serially-connected plurality of memory cells MC, for example. The semiconductor layer 110 may include the likes of non-doped polycrystalline silicon (Si), for example.

An insulating layer 111 is provided between two semiconductor layers 110 arranged in the X-direction. The insulating layer 111 may include the likes of silicon oxide (SiO₂), for example. The insulating layer 111 extends in the Z-direction penetrating the plurality of memory layers ML, as shown in FIG. 1, for example.

The memory cell region R_{MC} is provided with a plurality of via electrodes 120 arranged in the Y-direction along side surfaces on one side and the other side in the X-direction of the semiconductor layer 110. Moreover, in the memory cell region R_{MC}, the memory layer ML comprises a plurality of gate insulating layers 130 provided between the plurality of via electrodes 120 and the semiconductor layer 110.

A part of an outer peripheral surface of the via electrode 120 faces the semiconductor layer 110 via the gate insulating layer 130, and the remaining part faces the insulating layer 111. In the example illustrated, the outer peripheral surface of the via electrode 120 lies along a circle concentric with the via electrode 120. Moreover, a contact surface with the semiconductor layer 110 of the gate insulating layer 130 also lies along a circle concentric with the via electrode 120.

The via electrode 120 functions as the gate electrodes of a plurality of the memory cells MC and as the word line WL connected to these gate electrodes of a plurality of the memory cells MC, for example. The via electrode 120 may include a barrier conductive layer of the likes of titanium nitride (TiN), and a conductive layer of the likes of tungsten (W), for example. The via electrode 120 extends in the Z-direction penetrating the plurality of memory layers ML, as shown in FIG. 1, for example.

As shown in FIG. 4, the gate insulating layer 130 comprises, for example: a tunnel insulating layer 131 provided on a side surface in the X-direction of the semiconductor layer 110; an electric charge accumulating layer 132 provided on a side surface in the X-direction of the tunnel insulating layer 131; and a block insulating layer 133 provided on a side surface in the X-direction of the electric charge accumulating layer 132.

The tunnel insulating layer 131 may include the likes of silicon oxide (SiO₂), for example.

The electric charge accumulating layer 132 may include the likes of polycrystalline silicon (Si), for example. Moreover, this polycrystalline silicon (Si) may include an N-type impurity such as phosphorus (P) or P-type impurity such as boron (B), but need not include these impurities.

The block insulating layer 133 may include the likes of silicon oxide (SiO₂), for example. Moreover, the block insulating layer 133 may include an insulating metal oxide film (high dielectric constant insulating film) of aluminum oxide (AlO), hafnium oxide (HfO), or another insulating metal oxide.

The select transistor region R_{SGD} (FIG. 3) is provided with: a plurality of via electrodes 140 arranged in the Y-direction along a side surface on one side in the X-direction of the semiconductor layer 110; and a via wiring 150 provided on an opposite side of a center line CL to the plurality of via electrodes 140. Moreover, in the select transistor region R_{SGD}, the memory layer ML comprises a semiconductor layer 160 connected to one ends in the Y-direction of the plurality of semiconductor layers 110.

Note that the center line CL referred to here is a center line of the semiconductor layer 110 in an XY cross section. The center line CL is an imaginary straight line extending in the Y-direction. It is possible for a position in the X-direction of the center line CL to be stipulated by a mean value of a mean value of center positions in the X-direction of a plurality of the via electrodes 120 facing a side surface on one side in the X-direction of the semiconductor layer 110, and mean value of center positions in the X-direction of a plurality of the via electrodes 120 facing a side surface on the other side in the X-direction of the semiconductor layer 110, for example.

A part of an outer peripheral surface of the via electrode 140 faces the semiconductor layer 110, and the remaining part faces the insulating layer 111. A surface facing the semiconductor layer 110 of the via electrode 140 lies along a circle concentric with the via electrode 140.

The via electrode 140 in the select transistor region R_{SGD} functions as the gate electrodes of a plurality of the drain side select transistors STD and as the drain side select gate line SGD connected to these gate electrodes, for example. The via electrode 140 may include a barrier conductive layer of the likes of titanium nitride (TiN), and a conductive layer of the likes of tungsten (W), for example. The via electrode 140 extends in the Z-direction penetrating the plurality of memory layers ML. Moreover, the outer peripheral surface of the via electrode 140 is provided with an insulating layer 142 of the likes of silicon oxide (SiO₂) or aluminum oxide (Al₂O₃).

The via wiring 150 functions as the likes of a contact wiring for supplying holes to the semiconductor layer 110, for example. The via wiring 150 may include a semiconductor column which includes the likes of polycrystalline silicon (Si) including a P-type impurity such as boron (B), for example, and is formed in a circular column-like shape or cylindrical shape. Moreover, this semiconductor column may contact a plurality of the semiconductor layers 110 stacked in the Z-direction. The via wiring 150 extends in the Z-direction penetrating the plurality of memory layers ML.

The semiconductor layer 160 includes a semiconductor layer of the likes of polycrystalline silicon (Si) including an N-type impurity such as phosphorus (P) and being in contact with the semiconductor layer 110.

In the bit line region R_{BL} (FIG. 3), the memory layer ML comprises a conductive layer 170. Moreover, the bit line region R_{BL} is provided with a plurality of insulating layers 171 arranged in the X-direction along the conductive layer 170.

The conductive layer 170 functions as the bit line BL (FIG. 2), for example. The conductive layer 170 may include the likes of titanium nitride (TiN), for example. The conductive layer 170 extends in the X-direction, and is electrically connected to a plurality of the semiconductor layers 110, via the semiconductor layer 160.

The insulating layer 171 may include the likes of silicon oxide (SiO₂), for example. The insulating layer 171 extends in the Z-direction penetrating the plurality of memory layers ML.

The select transistor region R_{SGS} (FIG. 3) is provided with: a plurality of the via electrodes 140 arranged in the Y-direction along a side surface on one side in the X-direction of the semiconductor layer 110; and the via wiring 150 provided on an opposite side of the center line CL to the plurality of via electrodes 140.

The via electrode 140 in the select transistor region R_{SGS} functions as the gate electrodes of a plurality of the source side select transistors STS and as the source side select gate line SGS connected to these gate electrodes, for example.

The source line region R_{SL} is provided with a via wiring 180.

The via wiring 180 functions as the source line SL, for example. The via wiring 180 may include a semiconductor column which includes the likes of polycrystalline silicon (Si) including an N-type impurity such as phosphorus (P), for example, and is formed in a circular column-like shape or cylindrical shape. Moreover, this semiconductor column may contact a plurality of the semiconductor layers 110 stacked in the Z-direction. The via wiring 180 extends in the Z-direction penetrating the plurality of memory layers ML.

### Threshold Voltage of Memory Cell MC

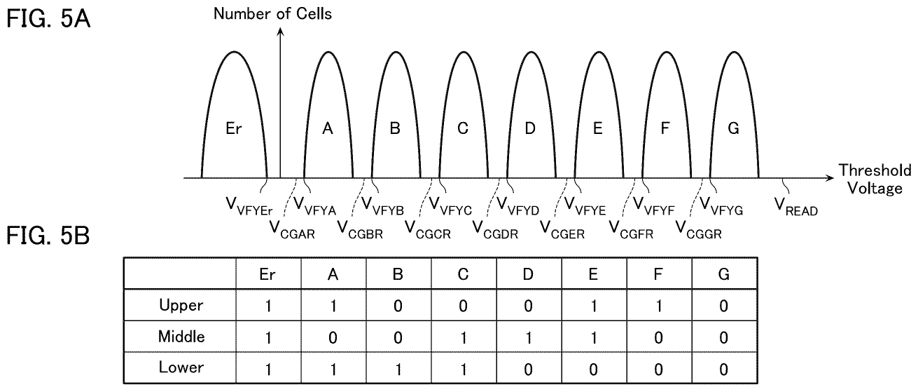

Next, threshold voltage of the memory cell MC will be described with reference to FIG. 5A and FIG. 5B.

FIG. 5A is a schematic histogram for explaining threshold voltage of the memory cell MC stored with 3 bits of data. The horizontal axis indicates voltage of the word line WL, and the vertical axis indicates number of memory cells MC. FIG. 5B is a table showing one example of a relationship of threshold voltage and stored data of the memory cell MC stored with 3 bits of data.

In the example of FIG. 5A, threshold voltage of the memory cell MC is controlled to eight types of states. Threshold voltages of the memory cells MC controlled to an Er state are less than an erase verify voltage V_{VFYEr}. Threshold voltages of the memory cells MC controlled to an A state are greater than a verify voltage V_{VFYA}, and less than a verify voltage V_{VFYB}. Threshold voltages of the memory cells MC controlled to a B state are greater than the verify voltage V_{VFYB}, and less than a verify voltage V_{VFYC}. Likewise, threshold voltages of the memory cells MC controlled to a C state through F state are respectively greater than the verify voltage V_{VFYC} through a verify voltage V_{VFYF}, and less than a verify voltage V_{VFYD} through a verify voltage V_{VFYG}. Threshold voltages of the memory cells MC controlled to a G state are greater than the verify voltage V_{VFYG}, and less than a read pass voltage V_{READ}.

Moreover, in the example of FIG. 5A, a read voltage V_{CGAR} is set to between a threshold distribution corresponding to the Er state and threshold distribution corresponding to the A state. Moreover, a read voltage V_{CGBR} is set to between the threshold distribution corresponding to the A state and a threshold distribution corresponding to the B state. Likewise, a read voltage V_{CGCR} through a read voltage V_{CGGR} are respectively set to between the threshold distribution corresponding to the B state and a threshold distribution corresponding to the C state through between a threshold distribution corresponding to the F state and threshold distribution corresponding to the G state.

For example, the Er state corresponds to a lowest threshold voltage. The memory cell MC in the Er state is the memory cell MC in an erased state. The memory cell MC in the Er state is assigned with data “111”, for example.

The A state corresponds to a higher threshold voltage than the above-described threshold voltage corresponding to the Er state. The memory cell MC in the A state is assigned with data “101”, for example.

Moreover, the B state corresponds to a higher threshold voltage than the above-described threshold voltage corresponding to the A state. The memory cell MC in the B state is assigned with data “001”, for example.

Likewise, the C state through G state in the drawings respectively correspond to higher threshold voltages than the threshold voltages corresponding to the B state through F state. The memory cells MC in these states are assigned with data “011”, “010”, “110”, “100”, “000”, for example.

In the case of assignation of the kind exemplified in FIG. 5B, lower bit data is discriminable by the single read voltage V_{CGDR}; middle bit data is discriminable by the three read voltages V_{CGAR}, V_{CGCR}, V_{CGFR}; and upper bit data is discriminable by the three read voltages V_{CGBR}, V_{CGER}, V_{CGGR}.

Note that the number of bits of data stored in the memory cell MC, the number of states, the assignation of data to each of the states, and so on, may be appropriately changed.

outline of Write Operation

Next, an outline of a write operation will be described. The write operation is executed on a plurality of the memory cells MC in the erased state (Er state). When the write operation is executed, these plurality of memory cells MC are controlled to any of the Er state through G state, depending on write data.

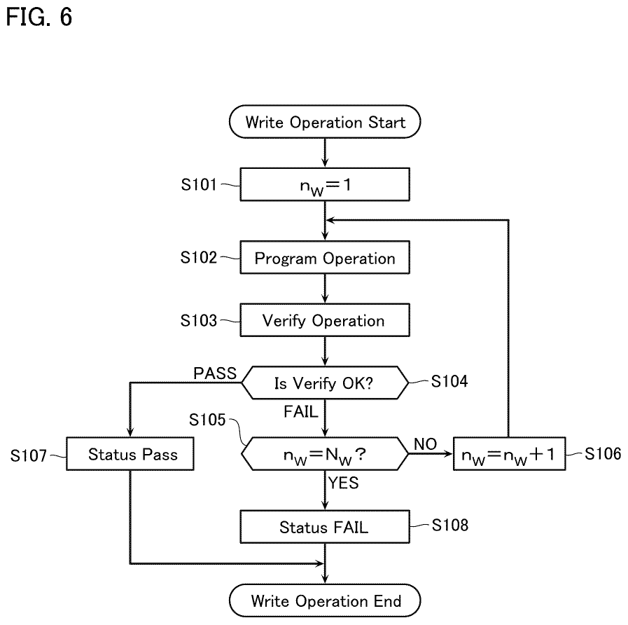

FIG. 6 is a flowchart for explaining the outline of the write operation.

In step S101, loop number n_{W} is set to 1. Loop number n_{W} is a variable indicating the number-of-times of write loops.

In step S102, a program operation is executed. The program operation is an operation for increasing threshold voltage of the memory cell MC by applying a selected word line WL_{S} with a program voltage, and accumulating an electric charge in the electric charge accumulating layer 132.

In step S103, a verify operation is performed. The verify operation is an operation for detecting whether threshold voltage of the memory cell MC has reached its target value, or not, by applying the selected word line WL_{S} with a verify voltage (for example, any of the verify voltages V_{VFYA}, V_{VFYB}, V_{VFYC}, V_{VFYD}, V_{VFYE}, V_{VFYF}, V_{VFYG} described with reference to FIG. 5), and detecting ON state/OFF state of the memory cell MC.

In step S104, a result of the verify operation is determined. For example, in such cases as when the number of memory cells MC whose threshold voltages have not reached their target value is a certain number or more, there is determined to have been a verify FAIL, and operation proceeds to step S105. On the other hand, in such cases as when the number of memory cells MC whose threshold voltages have not reached their target value is less than the certain number, there is determined to have been a verify PASS, and operation proceeds to step S107.

In step S105, it is determined whether loop number n_{W} has reached a certain number-of-times N_{W}, or not. When the certain number-of-times N_{W} has not been reached, then operation proceeds to step S106. When the certain number-of-times N_{W} has been reached, then operation proceeds to step S108.

In step S106, loop number n_{W} is increased by 1, whereby operation proceeds to step S102. Moreover, in step S106, a certain voltage ΔV is added to a program voltage V_{PGM}, for example. Hence, the program voltage V_{PGM} increases along with increase in the loop number n_{W}.

In step S107, status data indicating that the write operation ended normally is stored in a register, and the write operation is ended.

In step S108, status data indicating that the write operation did not end normally is stored in the register, and the write operation is ended.

### Outline of Program Operation

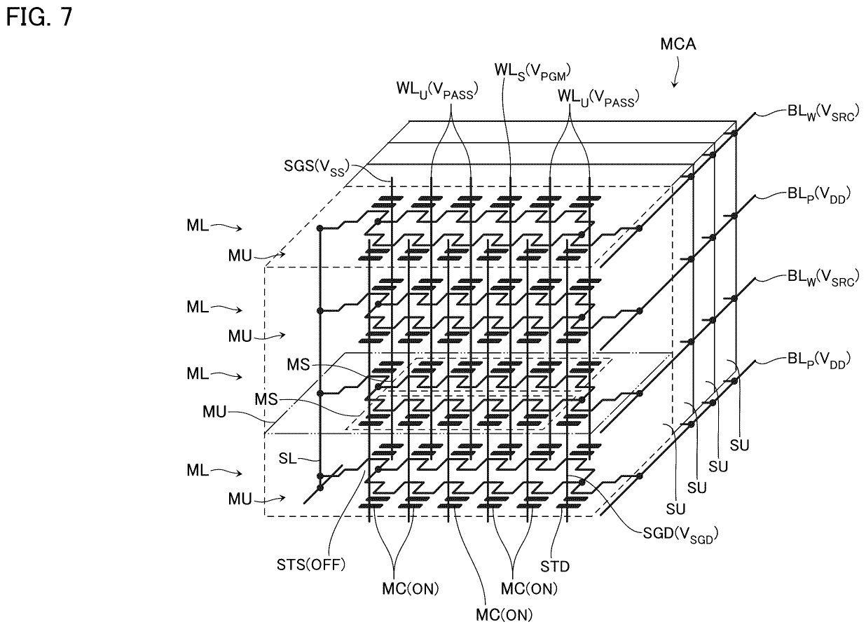

FIG. 7 is a schematic circuit diagram for explaining an outline of the program operation.

In the program operation, the plurality of memory cells MC connected to a single word line WL in one string unit SU are selected as selected memory cells MC. Hereafter, such a single word line WL will sometimes be referred to as a “selected word line WL_{S}”, and the other word lines WL will sometimes be referred to as “unselected word lines WL_{U}”.

In the program operation, for example, in a part of the plurality of selected memory cells MC, an electric field will be generated between their control gate electrode and channel, and electrons in the channel of the semiconductor layer 110 will be tunneled into the electric charge accumulating layer 132 (FIG. 4), thereby increasing threshold voltages of these parts of the selected memory cells MC.

Hereafter, a selected memory cell MC whose threshold voltage is increased will be referred to as a “write memory cell MC”. Moreover, a bit line BL connected to the write memory cell MC will be referred to as a bit line BL_{W}. Moreover, a selected memory cell MC whose threshold voltage is not increased will be referred to as a “prohibit memory cell MC”. Moreover, a bit line BL connected to a prohibit memory cell MC will be referred to as a bit line BL_{P}.

In the program operation, for example, the bit line BL_{W} is applied with a voltage V_{SRC}. Moreover, the bit line BL_{P} is applied with a voltage V_{DD}. Voltage V_{DD} is greater than voltage V_{SRC}.

Moreover, in the program operation, the drain side select gate line SGD corresponding to the string unit SU representing a target of the program operation is applied with a voltage V_{SGD}, and other drain side select gate lines SGD are applied with a voltage V_{OFF}.

Voltage V_{SGD} is greater than voltage V_{SRC}. Moreover, a voltage difference between voltage V_{SGD} and voltage V_{SRC} is greater than threshold voltage of the drain side select transistor STD when the drain side select transistor STD is operated as an NMOS transistor. Hence, a channel of electrons is formed in a channel region of the drain side select transistor STD connected to the bit line BL_{W}, and the voltage V_{SRC} is transferred to the channel region.

On the other hand, a voltage difference between voltage V_{SGD} and voltage V_{DD} is less than threshold voltage of the drain side select transistor STD when the drain side select transistor STD is operated as an NMOS transistor. Hence, the drain side select transistor STD connected to the bit line BL_{P} will be in an OFF state.

Voltage V_{OFF} has a magnitude such that the drain side select transistor STD will be in an OFF state, regardless of voltage of the bit line BL. Voltage V_{OFF} may have a negative magnitude, for example.

Moreover, in the program operation, the source line SL is applied with the voltage V_{SRC}, and the source side select gate line SGS is applied with a ground voltage V_{SS}. Now, a voltage difference between voltage V_{SRC} and ground voltage V_{SS} is less than threshold voltage of the source side select transistor STS when the source side select transistor STS is operated as an NMOS transistor. Hence, the source side select transistor STS will be in an OFF state.

Moreover, in the program operation, the unselected word lines WL_{U} are applied with a write pass voltage V_{PASS}. The write pass voltage V_{PASS} may be greater than the read pass voltage V_{READ} described with reference to FIG. 5, or may be the same level as the read pass voltage V_{READ}. A voltage difference between write pass voltage V_{PASS} and voltage V_{SRC} is greater than threshold voltage of the memory cell MC when the memory cell MC is operated as an NMOS transistor, regardless of data stored in the memory cell MC. Hence, a channel of electrons is formed in a channel region of an unselected memory cell MC electrically connected to the bit line BL_{W}, and the voltage V_{SRC} is transferred to the write memory cell MC.

Moreover, in the program operation, the selected word line WL_{S} is applied with the program voltage V_{PGM}. The program voltage V_{PGM} is greater than the write pass voltage V_{PASS}.

Now, the channel of the semiconductor layer 110 connected to the bit line BL_{W} is applied with the voltage V_{SRC}. A comparatively large electric field is generated between such a semiconductor layer 110 and the selected word line WL_{S}. As a result, electrons in the channel of the semiconductor layer 110 tunnel into the electric charge accumulating layer 132 (FIG. 4) via the tunnel insulating layer 131 (FIG. 4). Hence, threshold voltage of the write memory cell MC increases.

Moreover, the channel of the semiconductor layer 110 connected to the bit line BL_{P} is in an electrically floating state, and a potential of this channel rises to about the write pass voltage V_{PASS} due to capacitive coupling with the unselected word lines WL_{U}. Only an electric field less than the above-mentioned electric field is generated between such a semiconductor layer 110 and the selected word line WL_{S}. Therefore, electrons in the channel of the semiconductor layer 110 do not tunnel into the electric charge accumulating layer 132 (FIG. 4). Hence, threshold voltage of the prohibit memory cell MC does not increase.

### Outline of Verify Operation

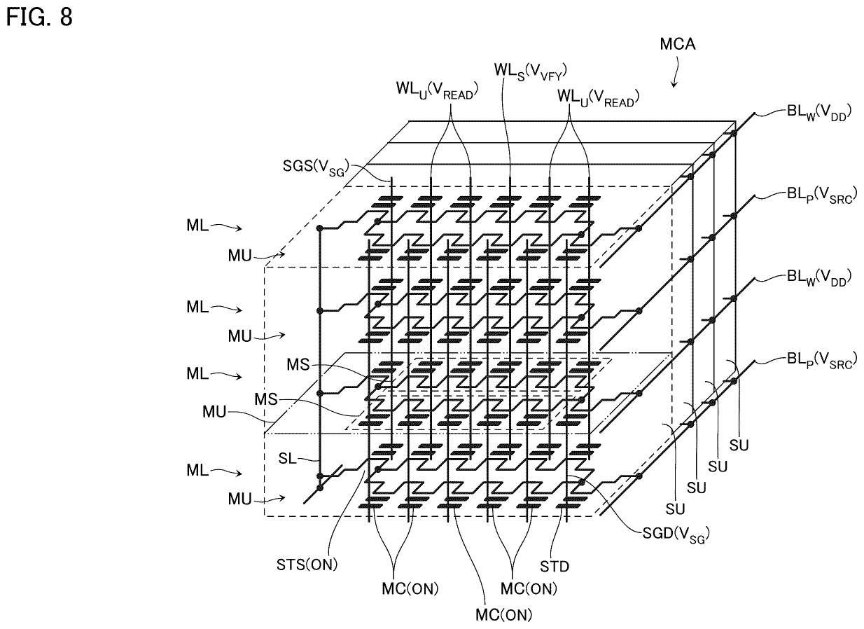

FIG. 8 is a schematic circuit diagram for explaining an outline of the verify operation.

In the verify operation, for example, the bit line BL_{W} is applied with the voltage V_{DD}. Moreover, the bit line BL_{P} is applied with the voltage V_{SRC}. Moreover, the source line SL is applied with the voltage V_{SRC}.

Moreover, in the verify operation, the drain side select gate line SGD is applied with a voltage V_{SG}. Voltage V_{SG} is greater than voltages V_{DD}, V_{SRC}. Moreover, a voltage difference between voltage V_{SG} and voltages V_{DD}, V_{SRC} is greater than threshold voltage of the drain side select transistor STD when the drain side select transistor STD is operated as an NMOS transistor. Hence, a channel of electrons is formed in the channel region of the drain side select transistor STD, and the voltages V_{DD}, V_{SRC} are transferred to the channel region.

Moreover, in the verify operation, the source side select gate line SGS is applied with the voltage V_{SG}. Hence, a channel of electrons is formed in the channel region of the source side select transistor STS, and the voltage V_{SRC} is transferred to the channel region.

Moreover, in the verify operation, the unselected word lines WL_{U} are applied with the read pass voltage V_{READ}. The read pass voltage V_{READ} is greater than voltages V_{DD}, V_{SRC}. Moreover, a voltage difference between the read pass voltage V_{READ} and voltages V_{DD}, V_{SRC} is greater than threshold voltage of the memory cell MC when the memory cell MC is operated as an NMOS transistor, regardless of data stored in the memory cell MC. Hence, a channel of electrons is formed in a channel region of the unselected memory cell MC, and the voltages V_{DD}, V_{SRC} are transferred to the selected memory cell MC.

Moreover, in the verify operation, the selected word line WL_{S} is applied with a verify voltage V_{VFY}. The verify voltage V_{VFY} is any of the verify voltages V_{VFYA}, V_{VFYB}, V_{VFYC}, V_{VFYD}, V_{VFYE}, V_{VFYF}, V_{VFYG} described with reference to FIG. 5. A voltage difference between the verify voltage V_{VFY} and voltage V_{SRC} is a target value of threshold voltage of the write memory cell MC. Therefore, a write memory cell MC whose threshold voltage has not reached the target value will be in an ON state. Hence, a current will flow in the bit line BL_{W} connected to such a write memory cell MC. On the other hand, a write memory cell MC whose threshold voltage has reached the target value will be in an OFF state. Hence, a current will not flow in the bit line BL_{W} connected to such a write memory cell MC.

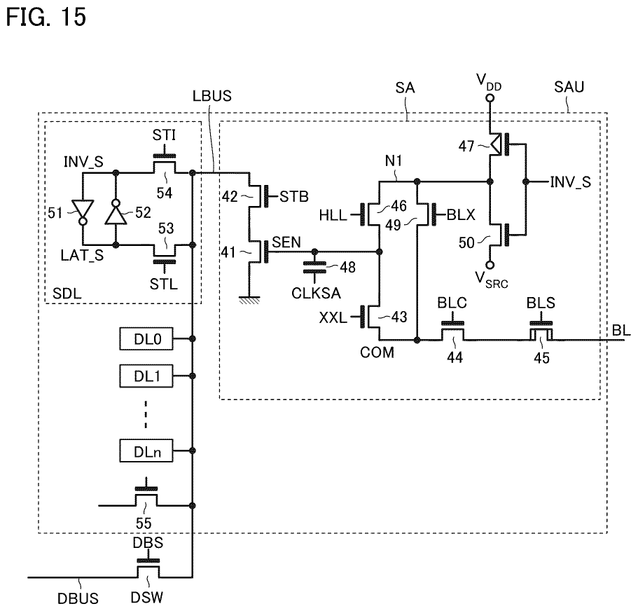

Moreover, in the verify operation, a later-mentioned sense amplifier unit SAU (FIG. 15) is used to detect whether current is flowing in the bit line BL, or not, whereby ON state/OFF state of the memory cell MC is detected. Hereafter, such an operation will sometimes be referred to as a “sense operation”.

[Differences in Characteristics between Memory Layers ML in Program Operation]

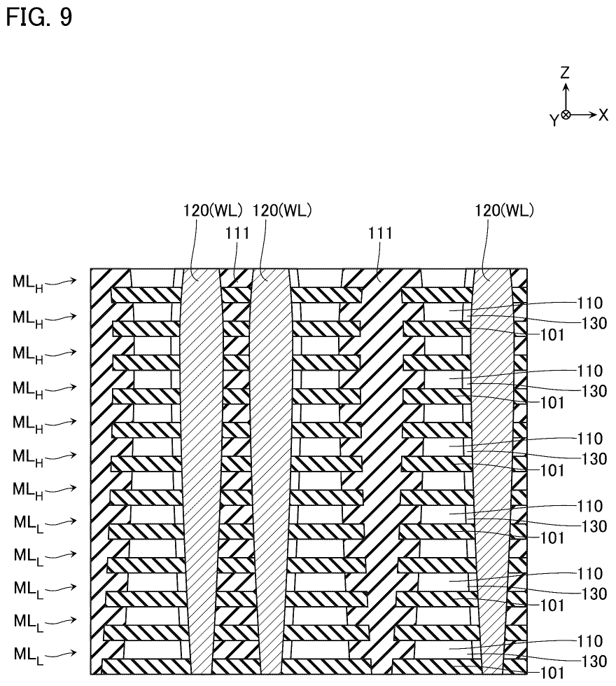

FIG. 9 is a schematic cross-sectional view showing a part of a configuration of the semiconductor memory device according to the first embodiment. When manufacturing the semiconductor memory device according to the first embodiment, a via hole is formed at a position corresponding to the via electrode 120 by a method such as RIE (Reactive Ion Etching), and the via electrode 120 is formed in this via hole. Now, sometimes, when a via hole of large aspect ratio is formed by a method such as RIE, width (diameter in an XY cross section) of the via electrode 120 will not be constant from its lower end to its upper end. In the example illustrated, width of the via electrode 120 is increasing from its lower end to a certain height position in a close vicinity of its upper end. Moreover, thickness of the via electrode 120 is decreasing from this certain height position to the upper end.

In such a structure, the more downwardly a memory layer ML is provided, the smaller the diameter in an XY cross section of the via electrode 120 becomes. In the example illustrated, a memory layer ML provided more downwardly than a certain height position is indicated as a memory layer ML_{L}. In the memory layer ML_{L}, it becomes easier for electric force lines to concentrate between the semiconductor layer 110 and via electrode 120, and application of the program voltage V_{PGM} results in a comparatively large amount of electric charge being accumulated in the electric charge accumulating layer 132.

On the other hand, in such a structure, the more upwardly a memory layer ML is provided, the larger the diameter in an XY cross section of the via electrode 120 becomes. In the example illustrated, a memory layer ML provided more upwardly than a certain height position is indicated as a memory layer ML_{H}. In the memory layer ML_{H}, it becomes harder for electric force lines to concentrate between the semiconductor layer 110 and via electrode 120, and application of the program voltage V_{PGM} results in a comparatively small amount of electric charge being accumulated in the electric charge accumulating layer 132.

In the present embodiment, in order to alleviate this kind of difference in characteristics of the memory layers ML in the program operation, the plurality of memory layers ML in the memory cell array MCA are divided into two or more groups depending on position in the Z-direction, and the voltage V_{SRC} applied to the bit lines BL in the program operation is adjusted for each group. Hereafter, examples assuming a plurality of the memory layers ML_{L} to be a first group and a plurality of the memory layers ML_{H} to be a second group, will be described.

Write Operation according to First Embodiment

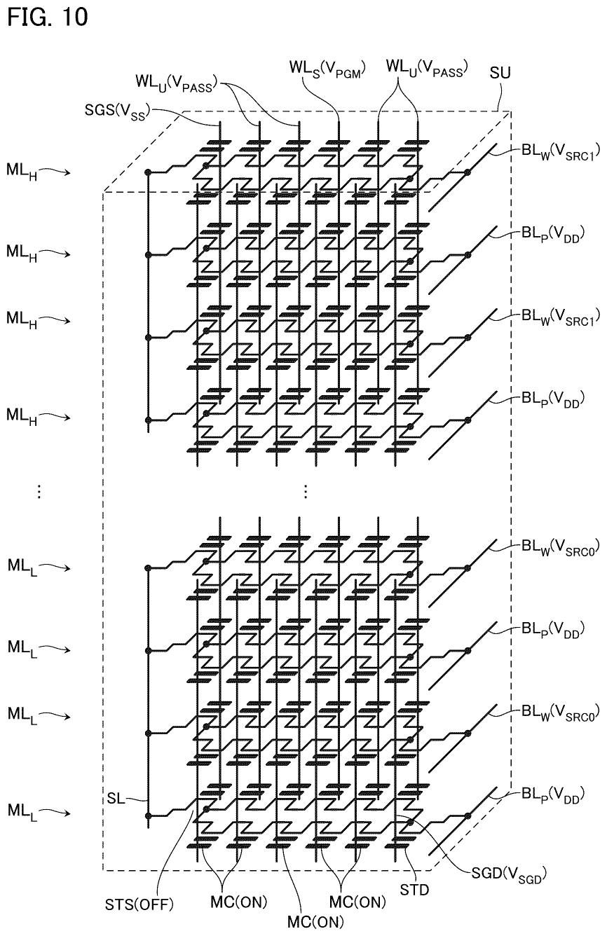

FIG. 10 is a schematic circuit diagram for explaining a write operation according to the present embodiment.

As described with reference to FIG. 7, in the program operation, the channel of the semiconductor layer 110 connected to the bit line BL_{W} is applied with the voltage V_{SRC}, the selected word line WL_{S} is applied with the program voltage V_{PGM}, and an FN tunnel is generated by the difference between the voltage V_{SRC} and program voltage V_{PGM}. Now, the smaller the voltage V_{SRC} is, the larger an inter-semiconductor layer 110-selected word line WL_{S} electric field will become, and the larger the amount of electric charge accumulated in the electric charge accumulating layer 132 will become.

Accordingly, in the first embodiment, as shown in FIG. 10, the voltage V_{SRC} applied to the bit line BL_{W} in the memory layer ML_{L} (hereafter, referred to as “voltage V_{SRC0}”) is made different from the voltage V_{SRC} applied to the bit line BL_{W} in the memory layer ML_{H} (hereafter, referred to as “voltage V_{SRC1}”). Moreover, voltage V_{SRC0} is set greater than voltage V_{SRC1}.

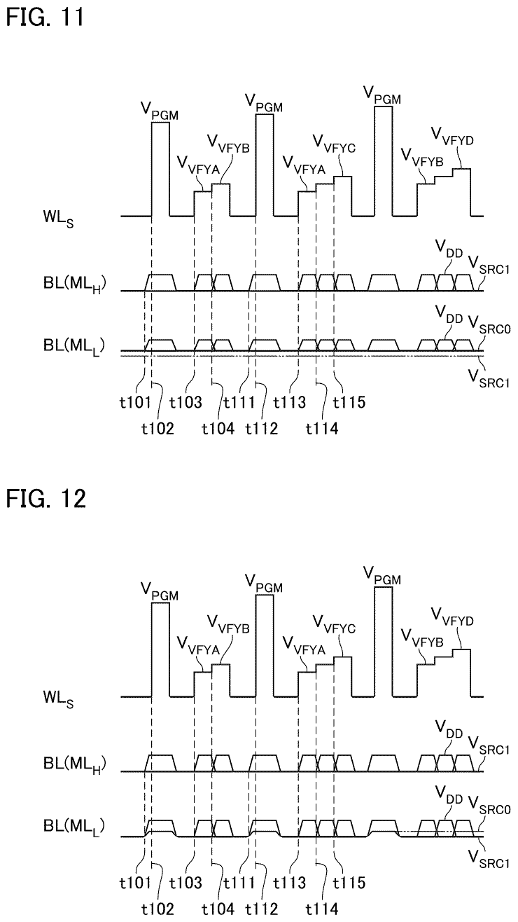

FIG. 11 is a schematic waveform diagram for explaining one example of the write operation according to the first embodiment.

In the example of FIG. 11, the program operation (step S102 of FIG. 6) is started at timing t101. Accordingly, the bit line BL_{W} in the memory layer ML_{H} is applied with voltage V_{SRC1}, and the bit line BL_{P} in the memory layer ML_{H} is applied with voltage V_{DD}. Moreover, the bit line BL_{W} in the memory layer ML_{L} is applied with voltage V_{SRC0}, and the bit line BL_{P} in the memory layer ML_{L} is applied with voltage V_{DD}.

Next, at timing t102, the selected word line WL_{S} is applied with the program voltage V_{PGM}.

Moreover, in the example of FIG. 11, the verify operation (step S103 of FIG. 6) is started at timing t103. In the example of FIG. 11, first, a state of the write memory cell MC controlled to the A state is detected. For example, the selected word line WL_{S} is applied with the verify voltage V_{VFYA}. Moreover, the bit line BL_{W} connected to the write memory cell MC controlled to the A state, of the bit lines BL in the memory layers ML_{H} is applied with the voltage V_{DD}, and the other bit lines BL in the memory layers ML_{H} are applied with the voltage V_{SRC1}. Moreover, the bit line BL_{W} connected to the write memory cell MC controlled to the A state, of the bit lines BL in the memory layers ML_{L} is applied with the voltage V_{DD}, and the other bit lines BL in the memory layers ML_{L} are applied with the voltage V_{SRC0}.

The sense operation is executed in this state, and it is determined whether threshold voltage of the write memory cell MC controlled to the A state has reached its target value, or not. At this time, a write memory cell MC whose threshold voltage has reached its target value is set to a prohibit memory cell MC.

Next, at timing t104, a state of the write memory cell MC controlled to the B state is detected. For example, the selected word line WL_{S} is applied with the verify voltage V_{VFYB}. Moreover, the bit line BL_{W} connected to the write memory cell MC controlled to the B state, of the bit lines BL in the memory layers ML_{H} is applied with the voltage V_{DD}, and the other bit lines BL in the memory layers ML_{H} are applied with the voltage V_{SRC1}. Moreover, the bit line BL_{W} connected to the write memory cell MC controlled to the B state, of the bit lines BL in the memory layers ML_{L} is applied with the voltage V_{DD}, and the other bit lines BL in the memory layers ML_{L} are applied with the voltage V_{SRC0}.

The sense operation is executed in this state, and it is determined whether threshold voltage of the write memory cell MC controlled to the B state has reached its target value, or not. At this time, a write memory cell MC whose threshold voltage has reached its target value is set to a prohibit memory cell MC.

Moreover, in the example of FIG. 11, at timing t111, the program operation is started. Accordingly, the bit lines BL are each applied with a similar voltage to the voltage applied at timing t101. However, a bit line BL connected to a memory cell MC set to a prohibit memory cell MC in the verify operation, is applied with voltage V_{DD}.

Next, at timing t112, the selected word line WL_{S} is applied with the program voltage V_{PGM}. Now, as described with reference to FIG. 6, in step S106, the certain voltage ΔV is added to the program voltage V_{PGM}. Hence, the program voltage V_{PGM} at timing t112 is greater than the program voltage V_{PGM} at timing t102.

Moreover, in the example of FIG. 11, the verify operation (step S103 of FIG. 6) is started at timing t113. At timing t113, a state of the write memory cell MC controlled to the A state is detected. At this time, a write memory cell MC whose threshold voltage has reached its target value is set to a prohibit memory cell MC.

Next, at timing t114, a state of the write memory cell MC controlled to the B state is detected. At this time, a write memory cell MC whose threshold voltage has reached its target value is set to a prohibit memory cell MC.

Next, at timing t115, a state of the write memory cell MC controlled to the C state is detected. At this time, a write memory cell MC whose threshold voltage has reached its target value is set to a prohibit memory cell MC.

Thereafter, likewise, the program operation and verify operation are repeatedly executed until verify PASS is determined in the operation of step S104 described with reference to FIG. 6, or until loop number n_{W} reaches the certain number-of-times N_{W} in the operation of step S105 described with reference to FIG. 6.

Note that in the example of FIG. 11, not only the voltage V_{SRC} applied to the bit lines BL in the program operation, but also the voltage V_{SRC} applied to the bit lines BL in the verify operation, is divided into voltages V_{SRC0}, V_{SRC1}. However, such an operation is merely an exemplification. The voltage V_{SRC} applied to the bit lines BL in the verify operation may be unified to voltage V_{SRC0} or voltage V_{SRC1}.

FIG. 12 is a schematic waveform diagram for explaining another example of the write operation according to the present embodiment. The write operation exemplified in FIG. 12 is executed substantially similarly to the write operation exemplified in FIG. 11. However, in the example of FIG. 12, the voltage V_{SRC} applied to the bit lines BL in the verify operation is unified to voltage V_{SRC1}.

### Advantages

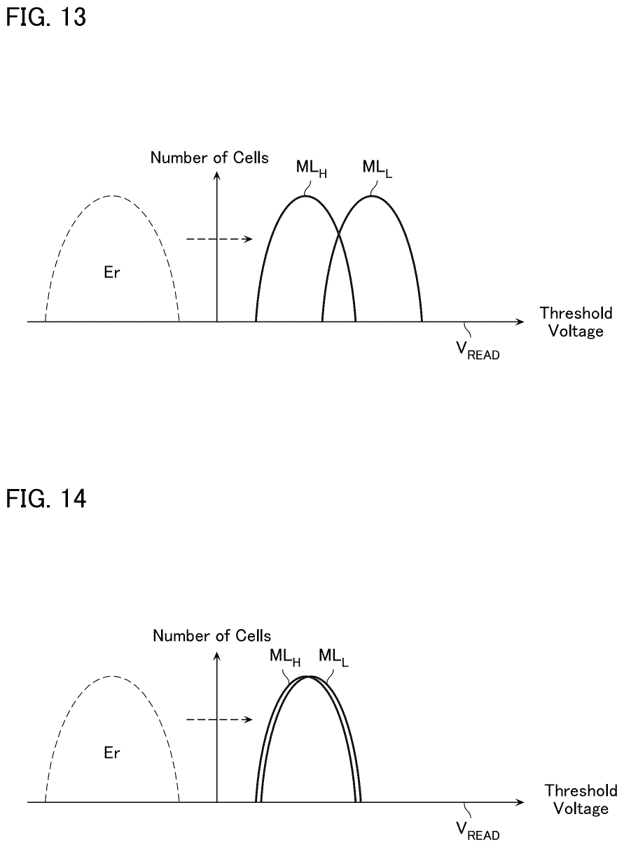

FIGS. 13 and 14 are schematic histograms for explaining advantages of the write operation according to the present embodiment.

FIG. 13 shows threshold distribution of the memory cells MC in the memory layer ML_{H} and threshold distribution of the memory cells MC in the memory layer ML_{L} in the case where voltage V_{SRC0} has been set to the same magnitude as voltage V_{SRC1} in the program operation and the selected word line WL_{S} has been applied with the program voltage in this state. In such a case, as illustrated, threshold voltage of the write memory cell MC in the memory layer ML_{L} will be greater than threshold voltage of the write memory cell MC in the memory layer ML_{H}. As a result, variation in threshold voltage of the memory cells MC will increase.

FIG. 14 shows threshold distribution of the memory cells MC in the memory layer ML_{H} and threshold distribution of the memory cells MC in the memory layer ML_{L} in the case where voltage V_{SRC0} has been set greater than voltage V_{SRC1} in the program operation and the selected word line WL_{S} has been applied with the program voltage in this state. As illustrated, such a method results in threshold voltage of the write memory cell MC in the memory layer ML_{L} having the same level of magnitude as threshold voltage of the write memory cell MC in the memory layer ML_{H}. This enables variation in threshold voltage of the memory cells MC to be suppressed.

### Peripheral Circuit

FIG. 15 is a schematic circuit diagram showing a configuration example of a part of the peripheral circuit of the semiconductor memory device according to the present embodiment.

The semiconductor memory device according to the present embodiment comprises a plurality of sense amplifier units SAU provided correspondingly to the plurality of bit lines BL, as a part of its peripheral circuit. The sense amplifier unit SAU comprises a sense amplifier SA, a wiring LBUS, and latch circuits SDL, DL0-DLn (where n is a natural number). The wiring LBUS is connected with a charge transistor 55 for pre-charging. The wiring LBUS is connected to a wiring DBUS via a switch transistor DSW.

The sense amplifier SA comprises a sense transistor 41. The sense transistor 41 discharges a charge of the wiring LBUS depending on a current flowing in the bit line BL, in the above-mentioned sense operation. A source electrode of the sense transistor 41 is connected to a voltage supply line applied with the ground voltage V_{SS}. A drain electrode of the sense transistor 41 is connected to the wiring LBUS via a switch transistor 42. A gate electrode of the sense transistor 41 is connected to the bit line BL via a sense node SEN, a discharge transistor 43, a node COM, a clamp transistor 44, and a voltage-withstanding transistor 45. Note that the sense node SEN is connected to a signal line CLKSA via a capacitor 48.

Moreover, the sense amplifier SA comprises a voltage transfer circuit. The voltage transfer circuit selectively makes the node COM and the sense node SEN electrically conductive with a voltage supply line applied with the voltage V_{DD} or voltage supply line applied with the voltage V_{SRC}, depending on data latched in the latch circuit SDL. The voltage transfer circuit comprises a node N1, a charge transistor 46, a charge transistor 49, a charge transistor 47, and a discharge transistor 50. The charge transistor 46 is connected between the node N1 and the sense node SEN. The charge transistor 49 is connected between the node N1 and the node COM. The charge transistor 47 is connected between the node N1 and the voltage supply line applied with the voltage V_{DD}. The discharge transistor 50 is connected between the node N1 and the voltage supply line applied with the voltage V_{SRC}. Note that gate electrodes of the charge transistor 47 and the discharge transistor 50 are commonly connected to a node INV_S of the latch circuit SDL.

Note that the sense transistor 41, the switch transistor 42, the discharge transistor 43, the clamp transistor 44, the charge transistor 46, the charge transistor 49, and the discharge transistor 50 are enhancement type NMOS transistors, for example. The voltage-withstanding transistor 45 is a depletion type NMOS transistor, for example. The charge transistor 47 is a PMOS transistor, for example.

Moreover, a gate electrode of the switch transistor 42 is connected to a signal line STB. A gate electrode of the discharge transistor 43 is connected to a signal line XXL. A gate electrode of the clamp transistor 44 is connected to a signal line BLC. A gate electrode of the voltage-withstanding transistor 45 is connected to a signal line BLS. A gate electrode of the charge transistor 46 is connected to a signal line HLL. A gate electrode of the charge transistor 49 is connected to a signal line BLX. These signal lines STB, XXL, BLC, BLS, HLL, BLX are connected to an unillustrated control circuit.

The latch circuit SDL comprises a node LAT_S and the node INV_S, an inverter 51, an inverter 52, a switch transistor 53, and a switch transistor 54. The inverter 51 comprises an output terminal connected to the node LAT_S and an input terminal connected to the node INV_S. The inverter 52 comprises an input terminal connected to the node LAT_S and an output terminal connected to the node INV_S. The switch transistor 53 is provided in a current path between the node LAT_S and the wiring LBUS. The switch transistor 54 is provided in a current path between the node INV_S and the wiring LBUS. The switch transistors 53, 54 are NMOS transistors, for example. A gate electrode of the switch transistor 53 is connected to the unillustrated control circuit via a signal line STL. A gate electrode of the switch transistor 54 is connected to the unillustrated control circuit via a signal line STI.

The latch circuits DL0-DLn are configured substantially similarly to the latch circuit SDL. However, as mentioned above, the node INV_S of the latch circuit SDL is electrically conductive with the gate electrodes of the charge transistor 47 and the discharge transistor 50 in the sense amplifier SA. The latch circuits DL0-DLn differ from the latch circuit SDL in this respect.

The switch transistor DSW is an NMOS transistor, for example. The switch transistor DSW is connected between the wiring LBUS and the wiring DBUS. A gate electrode of the switch transistor DSW is connected to the unillustrated control circuit via a signal line DBS.

The signal lines STB, HLL, XXL, BLX, BLC, BLS are each commonly connected to all of the sense amplifier units SAU included in the semiconductor memory device. Moreover, the voltage supply line applied with the voltage V_{DD} and the voltage supply line applied with the voltage V_{SRC} are each commonly connected to a plurality of the sense amplifier units SAU included in the semiconductor memory device. Moreover, the signal line STI and the signal line STL of the latch circuit SDL are each commonly connected to all of the sense amplifier units SAU included in the semiconductor memory device. Similarly, signal lines TI0-TIn, TL0-TLn corresponding to the signal lines STI and signal lines STL in the latch circuits DL0-DLn are each commonly connected to all of the sense amplifier units SAU included in the semiconductor memory device.

In the program operation, the latch circuit SDL corresponding to the above-described write memory cell MC is latched with “L”. As a result, the charge transistor 47 attains an OFF state, the discharge transistor 50 attains an ON state, and node N1 is applied with the voltage V_{SRC}. On the other hand, the latch circuit SDL corresponding to the above-described prohibit memory cell MC is latched with “H”. As a result, the charge transistor 47 attains an ON state, the discharge transistor 50 attains an OFF state, and node N1 is applied with the voltage V_{DD}. Setting the charge transistor 49, clamp transistor 44, and voltage-withstanding transistor 45 to an ON state in this state makes it possible for the bit line BL_{W} to be applied with the voltage V_{SRC}, and the bit line BL_{P} to be applied with the voltage V_{DD}.

In the verify operation, the latch circuit SDL corresponding to the above-described write memory cell MC is latched with “H”, and the latch circuit SDL corresponding to the above-described prohibit memory cell MC is latched with “L”. Setting the charge transistor 49, clamp transistor 44, and voltage-withstanding transistor 45 to an ON state in this state makes it possible for the bit line BL_{W} to be applied with the voltage V_{DD}, and the bit line BL_{P} to be applied with the voltage V_{SRC}.

Prior to execution of the sense operation, the signal line HLL is set to an “H” state, and the signal line XXL is set to an “L” state. As a result, the charge transistor 46 attains an ON state, the discharge transistor 43 attains an OFF state, and charging of the sense node SEN corresponding to the write memory cell MC is performed. Moreover, the signal line STB is set to an “L” state and the charge transistor 55 set for a certain time to an ON state, whereby charging of the wiring LBUS is performed.

When executing the sense operation, the signal lines XXL, CLKSA are set to an “H” state. As a result, the discharge transistor 43 attains an ON state, and, moreover, voltage of the sense node SEN rises due to capacitive coupling. Now, when current flows in the bit line BL, that is, when the selected memory cell MC is in an ON state, electric charge in the sense node SEN is discharged. On the other hand, when current does not flow in the bit line BL, that is, when the selected memory cell MC is in an OFF state, electric charge in the sense node SEN is maintained. After a certain time has elapsed, the signal lines XXL, CLKSA are set to an “L” state. As a result, in the case of electric charge in the sense node SEN having been discharged, the sense transistor 41 will be in an OFF state, and in the case of electric charge in the sense node SEN having not been discharged, the sense transistor 41 will be in an ON state.

Next, the signal line STB is set to an “H” state. As a result, in the case of the sense transistor 41 being in an OFF state, electric charge of the wiring LBUS is maintained, and in the case of the sense transistor 41 being in an ON state, electric charge of the wiring LBUS is discharged. This makes it possible to detect a write memory cell MC whose threshold voltage has reached its target value.

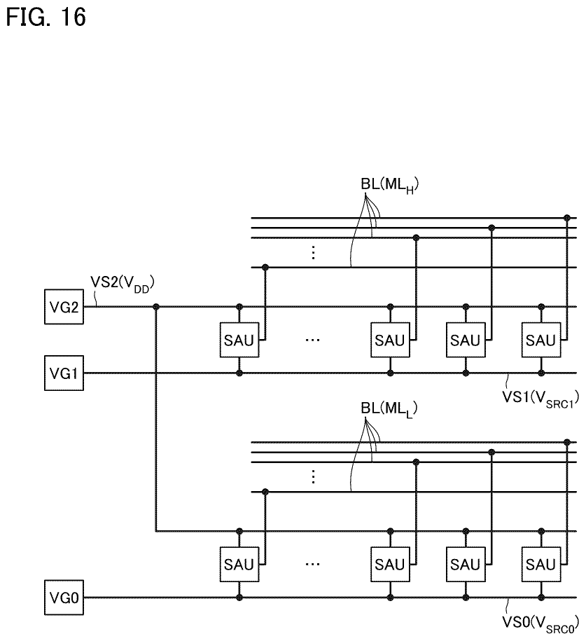

FIG. 16 is a schematic circuit diagram showing a configuration example of a part of the peripheral circuit of the semiconductor memory device according to the present embodiment.

The semiconductor memory device according to the present embodiment comprises voltage generating circuits VG0, VG1, VG2, as a part of its peripheral circuit. The voltage generating circuits VG0, VG1, VG2 are each a booster circuit such as a charge pump circuit, or a step-down circuit such as a regulator circuit.

An output terminal of the voltage generating circuit VG0 is connected to a voltage supply line VS0. The voltage generating circuit VG0 applies the voltage supply line VS0 with the voltage V_{SRC0}. The voltage supply line VS0 is commonly connected to those sense amplifier units SAU that are connected to bit lines BL in the memory layers ML_{L}, of the plurality of sense amplifier units SAU included in the semiconductor memory device. As a result, the plurality of sense amplifier units SAU corresponding to the memory layers ML_{L} are applied with the voltage V_{SRC0} as the voltage V_{SRC}.

An output terminal of the voltage generating circuit VG1 is connected to a voltage supply line VS1. The voltage generating circuit VG1 applies the voltage supply line VS1 with the voltage V_{SRC1}. The voltage supply line VS1 is commonly connected to those sense amplifier units SAU that are connected to bit lines BL in the memory layers ML_{H}, of the plurality of sense amplifier units SAU included in the semiconductor memory device. As a result, the plurality of sense amplifier units SAU corresponding to the memory layers ML_{H} are applied with the voltage V_{SRC1} as the voltage V_{SRC}.

An output terminal of the voltage generating circuit VG2 is connected to a voltage supply line VS2. The voltage generating circuit VG2 applies the voltage supply line VS2 with the voltage V_{DD}. The voltage supply line VS2 is commonly connected to all of the sense amplifier units SAU included in the semiconductor memory device.

Such a configuration makes it possible to execute the write operation of the kind described with reference to FIG. 11.

Note that in the case where, as described with reference to FIG. 12, for example, the voltage V_{SRC} applied to the bit lines BL in the verify operation is unified to voltage V_{SRC0} or voltage V_{SRC1}, the voltage outputted from the voltage generating circuits VG0, VG1 in the verify operation may be unified to voltage V_{SRC0} or voltage V_{SRC1}, or the voltage supply lines VS0, VS1 and voltage generating circuits VG0, VG1 may be connected via a multiplexer, or the like.

### Second Embodiment

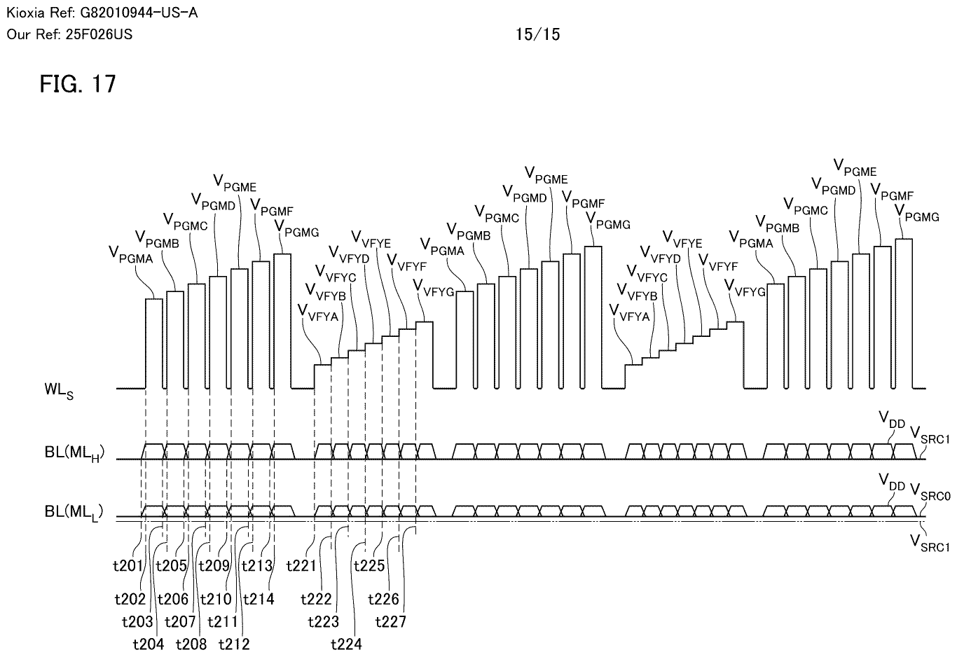

FIG. 17 is a schematic waveform diagram for explaining one example of a write operation according to a second embodiment. In the following description, portions similar to in the first embodiment will be assigned with the same symbols as in the first embodiment, and descriptions thereof omitted.

In the example of FIG. 17, the program operation (step S102 of FIG. 6) is started at timing t201. In the example of FIG. 17, first, threshold voltage of the write memory cell MC controlled to the A state is adjusted. For example, the bit line BL_{W} connected to the write memory cell MC controlled to the A state, of the bit lines BL in the memory layers ML_{H} is applied with the voltage V_{SRC1}, and the other bit lines BL in the memory layers ML_{H} are applied with the voltage V_{DD}. Moreover, the bit line BL_{W} connected to the write memory cell MC controlled to the A state, of the bit lines BL in the memory layers ML_{L} is applied with the voltage V_{SRC0}, and the other bit lines BL in the memory layers ML_{L} are applied with the voltage V_{DD}.

Next, at timing t202, the selected word line WL_{S} is applied with a program voltage V_{PGMA}.

Next, at timing t203, threshold voltage of the write memory cell MC controlled to the B state is adjusted. For example, the bit line BL_{W} connected to the write memory cell MC controlled to the B state, of the bit lines BL in the memory layers ML_{H} is applied with the voltage V_{SRC1}, and the other bit lines BL in the memory layers ML_{H} are applied with the voltage V_{DD}. Moreover, the bit line BL_{W} connected to the write memory cell MC controlled to the B state, of the bit lines BL in the memory layers ML_{L} is applied with the voltage V_{SRC0}, and the other bit lines BL in the memory layers ML_{L} are applied with the voltage V_{DD}.

Next, at timing t204, the selected word line WL_{S} is applied with a program voltage V_{PGMB}. Program voltage V_{PGMB} is greater than program voltage V_{PGMA}.

Thereafter, likewise, at timing t205 through timing t214, threshold voltages of the write memory cell MC controlled to the C state through G state are adjusted. Note that FIG. 17 exemplifies program voltages V_{PGMC}, V_{PGMD}, V_{PGME}, V_{PGMF}, V_{PGMG} as the program voltage V_{PGM} corresponding to the C state through G state. Program voltage V_{PGMC} is greater than program voltage V_{PGMB}. Program voltage V_{PGMD} is greater than program voltage V_{PGMC}. Program voltage V_{PGME} is greater than program voltage V_{PGMD}. Program voltage V_{PGMF} is greater than program voltage V_{PGME}. Program voltage V_{PGMG} is greater than program voltage V_{PGMF}.

Moreover, in the example of FIG. 17, the verify operation (step S103 of FIG. 6) is started at timing t221. The verify operation according to the second embodiment is basically executed similarly to the verify operation according to the first embodiment. However, in the verify operation according to the first embodiment, states of write memory cells MC corresponding to only a part of the A state through G state are detected in each verify operation. On the other hand, in the verify operation according to the second embodiment, states of write memory cells MC in all of the A state through G state are detected in each verify operation.

In the second embodiment, too, similarly to in the first embodiment, the program operation and verify operation are repeatedly executed until verify PASS is determined in the operation of step S104 described with reference to FIG. 6, or until loop number n_{W} reaches the certain number-of-times N_{W} in the operation of step S105 described with reference to FIG. 6.

In the second embodiment, in step S106 of FIG. 6, the certain voltage ΔV is added to all of the program voltages V_{PGMA}, V_{PGMB}, V_{PGMC}, V_{PGMD}, V_{PGME}, V_{PGMF}, V_{PGMG}.

Note that in the second embodiment, too, as described with reference to FIG. 12, for example, the voltage V_{SRC} applied to the bit lines BL in the verify operation may be unified to voltage V_{SRC0} or voltage V_{SRC1}.

### Other Embodiments

That concludes description of the semiconductor memory devices according to the first embodiment and the second embodiment. However, the configurations and operations of the kind described above are merely exemplifications, and specific configurations, methods, and so on, may be appropriately adjusted.

For example, in the write operations according to the first embodiment and the second embodiment, there are shown examples where the plurality of memory layers ML in the memory cell array MCA are divided into two groups, and the voltage V_{SRC} applied to the bit lines BL in the program operation is adjusted for each of these two groups. However, the plurality of memory layers ML in the memory cell array MCA may be divided into three or more groups. Moreover, the voltage V_{SRC} applied to the bit lines BL in the program operation, too, may be adjusted for each of these three groups.

Moreover, in the first embodiment and the second embodiment, referring to FIG. 9, there are shown examples where width of the via electrode 120 increases from its lower end to a certain height position in a close vicinity of its upper end, and decreases from this certain height position to the upper end. However, depending on method of manufacturing, thickness of the via electrode 120 will also sometimes increase monotonically from its lower end to its upper end. Moreover, when the above-mentioned kind of via hole is formed a portion at a time on a plurality of occasions, then width of the via electrode 120 will also sometimes increase and decrease substantially cyclically from its lower end to its upper end. Moreover, if, for example, a wafer corresponding to the memory cell array MCA and a wafer corresponding to the peripheral circuit have been manufactured separately, the wafer corresponding to the memory cell array MCA has been bonded upwardly/downwardly-inverted to the wafer corresponding to the peripheral circuit, and, furthermore, a substrate has been removed from the wafer corresponding to the memory cell array MCA, then, with reference made to a substrate of the wafer corresponding to the peripheral circuit, shape of the via electrode 120 will also sometimes be upwardly/downwardly reversed.

In these cases, too, it is possible for the plurality of memory layers ML in the memory cell array MCA to be divided into two or more groups depending on their height position, and for the voltage V_{SRC} applied to the bit lines BL in the program operation to be adjusted for each of the groups. That is, it is possible for the voltage V_{SRC} applied to the bit lines BL in the program operation to be adjusted to a comparatively large value in a group including memory layers ML where diameter in an XY cross section of the via electrode 120 is comparatively small. Moreover, it is possible for the voltage V_{SRC} applied to the bit lines BL in the program operation to be adjusted to a comparatively small value in a group including memory layers ML where diameter in an XY cross section of the via electrode 120 is comparatively large.

Moreover, in the first embodiment and the second embodiment, the voltage V_{DD} applied to the bit lines BL in at least one of the program operation or the verify operation may also be adjusted for each group.

Moreover, in the first embodiment and the second embodiment, there are described examples where threshold voltage of the memory cell MC is adjusted to eight types of states, whereby 3 bits of data are stored in the memory cell MC. However, the memory cell MC may have 2 or less bits of data stored therein, or may have 4 or more bits of data stored therein.

Moreover, in the examples of FIGS. 11, 12, and 17, in the verify operation, states are detected in order from the write memory cell MC controlled to a state whose threshold voltage is small, of the A state through G state. However, in the examples of FIGS. 11, 12, and 17, in the verify operation, states may be detected in order from the write memory cell MC controlled to a state whose threshold voltage is large, of the A state through G state.

Moreover, in the example of FIG. 17, in the program operation, threshold voltage is adjusted in order from the write memory cell MC controlled to a state whose threshold voltage is small, of the A state through G state. However, in the example of FIG. 17, in the program operation, threshold voltage may be adjusted in order from the write memory cell MC controlled to a state whose threshold voltage is large, of the A state through G state.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of semiconductor layers stacked in a stacking direction and extending in a first direction intersecting the stacking direction;
a plurality of conductive layers which are stacked in the stacking direction correspondingly to the plurality of semiconductor layers, extend in a second direction intersecting the stacking direction and the first direction, and are connected to end portions in the first direction of the plurality of semiconductor layers;
a plurality of via electrodes which are arranged in the first direction along side surfaces in the second direction of the plurality of semiconductor layers, extend in the stacking direction, face the plurality of semiconductor layers, and have diameters that increase from a first position to a second position in the stacking direction; and
a plurality of electric charge accumulating layers provided between the plurality of semiconductor layers and the plurality of via electrodes, wherein
at a first timing of a program operation causing an electric charge to be accumulated in a part of the plurality of electric charge accumulating layers,
in a state where a plurality of first conductive layers provided in a range from the first position in the stacking direction to a third position between the first position and the second position in the stacking direction, of the plurality of conductive layers, have been applied with a first voltage or with a second voltage greater than the first voltage, and
a plurality of second conductive layers provided in a range from the second position in the stacking direction to a fourth position between the second position and the third position in the stacking direction, of the plurality of conductive layers, have been applied with a third voltage greater than the first voltage and less than the second voltage, or with a fourth voltage greater than the third voltage,
one of the plurality of via electrodes is applied with a first program voltage.

2. The semiconductor memory device according to claim 1, wherein
at the first timing,
those corresponding to the part of the plurality of electric charge accumulating layers, of the plurality of first conductive layers are applied with the first voltage,
those not corresponding to the part of the plurality of electric charge accumulating layers, of the plurality of first conductive layers are applied with the second voltage,
those corresponding to the part of the plurality of electric charge accumulating layers, of the plurality of second conductive layers are applied with the third voltage, and
those not corresponding to the part of the plurality of electric charge accumulating layers, of the plurality of second conductive layers are applied with the fourth voltage.

3. The semiconductor memory device according to claim 1, wherein
the part of the plurality of electric charge accumulating layers includes an electric charge accumulating layer controlled to a second state from a first state, and
at the first timing,
those corresponding to the electric charge accumulating layers controlled to the second state, of the plurality of first conductive layers are applied with the first voltage,
others than those corresponding to the electric charge accumulating layers controlled to the second state, of the plurality of first conductive layers are applied with the second voltage,
those corresponding to the electric charge accumulating layers controlled to the second state, of the plurality of second conductive layers are applied with the third voltage, and
others than those corresponding to the electric charge accumulating layers controlled to the second state, of the plurality of second conductive layers are applied with the fourth voltage.

4. The semiconductor memory device according to claim 3, wherein
the part of the plurality of electric charge accumulating layers further includes an electric charge accumulating layer controlled to a third state from the first state, and
at a second timing of the program operation,
in a state where those corresponding to the electric charge accumulating layers controlled to the third state, of the plurality of first conductive layers have been applied with the first voltage,
others than those corresponding to the electric charge accumulating layers controlled to the third state, of the plurality of first conductive layers have been applied with the second voltage,
those corresponding to the electric charge accumulating layers controlled to the third state, of the plurality of second conductive layers have been applied with the third voltage, and
others than those corresponding to the electric charge accumulating layers controlled to the third state, of the plurality of second conductive layers have been applied with the fourth voltage,
the one of the plurality of via electrodes is applied with a second program voltage greater than the first program voltage.

5. The semiconductor memory device according to claim 1, further comprising:
a plurality of first sense amplifier circuits electrically connected to the plurality of first conductive layers;
a first voltage supply line capable of applying the first voltage to the plurality of first sense amplifier circuits;
a second voltage supply line capable of applying the second voltage to the plurality of first sense amplifier circuits;
a plurality of second sense amplifier circuits electrically connected to the plurality of second conductive layers;
a third voltage supply line capable of applying the third voltage to the plurality of second sense amplifier circuits; and
a fourth voltage supply line capable of applying the fourth voltage to the plurality of second sense amplifier circuits.

6. The semiconductor memory device according to claim 5, further comprising:
a plurality of first latch circuits provided correspondingly to the plurality of first sense amplifier circuits; and
a plurality of second latch circuits provided correspondingly to the plurality of second sense amplifier circuits, wherein
the plurality of first sense amplifier circuits each make the plurality of first conductive layers electrically conductive with the first voltage supply line or the second voltage supply line, depending on data latched in the plurality of first latch circuits, and
the plurality of second sense amplifier circuits each make the plurality of second conductive layers to be electrically conductive with the third voltage supply line or the fourth voltage supply line, depending on data latched in the plurality of second latch circuits.

7. A semiconductor memory device comprising:
a plurality of semiconductor layers stacked in a stacking direction and extending in a first direction intersecting the stacking direction;
a plurality of conductive layers which are stacked in the stacking direction correspondingly to the plurality of semiconductor layers, extend in a second direction intersecting the stacking direction and the first direction, and are connected to end portions in the first direction of the plurality of semiconductor layers;
a plurality of via electrodes which are arranged in the first direction along side surfaces in the second direction of the plurality of semiconductor layers, extend in the stacking direction, face the plurality of semiconductor layers, and have diameters that increase from a first position to a second position in the stacking direction;
a plurality of electric charge accumulating layers provided between the plurality of semiconductor layers and the plurality of via electrodes;
a plurality of first sense amplifier circuits electrically connected to a plurality of first conductive layers provided in a range from the first position in the stacking direction to a third position between the first position and the second position in the stacking direction, of the plurality of conductive layers;
a first voltage supply line capable of applying a first voltage to the plurality of first sense amplifier circuits;
a second voltage supply line capable of applying a second voltage different from the first voltage, to the plurality of first sense amplifier circuits;
a plurality of second sense amplifier circuits electrically connected to a plurality of second conductive layers provided in a range from the second position in the stacking direction to a fourth position between the second position and the third position in the stacking direction, of the plurality of conductive layers;
a third voltage supply line capable of applying a third voltage different from the first voltage and the second voltage, to the plurality of second sense amplifier circuits; and
a fourth voltage supply line capable of applying a fourth voltage different from the first voltage and the third voltage, to the plurality of second sense amplifier circuits.

8. The semiconductor memory device according to claim 7, further comprising:
a plurality of first latch circuits provided correspondingly to the plurality of first sense amplifier circuits; and
a plurality of second latch circuits provided correspondingly to the plurality of second sense amplifier circuits, wherein
the plurality of first sense amplifier circuits each make the plurality of first conductive layers electrically conductive with the first voltage supply line or the second voltage supply line, depending on data latched in the plurality of first latch circuits, and
the plurality of second sense amplifier circuits each make the plurality of second conductive layers electrically conductive with the third voltage supply line or the fourth voltage supply line, depending on data latched in the plurality of second latch circuits.

9. A method of controlling a semiconductor memory device comprising:
a plurality of semiconductor layers stacked in a stacking direction and extending in a first direction intersecting the stacking direction;
a plurality of conductive layers which are stacked in the stacking direction correspondingly to the plurality of semiconductor layers, extend in a second direction intersecting the stacking direction and the first direction, and are connected to end portions in the first direction of the plurality of semiconductor layers;
a plurality of via electrodes which are arranged in the first direction along side surfaces in the second direction of the plurality of semiconductor layers, extend in the stacking direction, face the plurality of semiconductor layers, and have diameters that increase from a first position to a second position in the stacking direction; and
a plurality of electric charge accumulating layers provided between the plurality of semiconductor layers and the plurality of via electrodes, wherein
at a first timing of a program operation causing an electric charge to be accumulated in a part of the plurality of electric charge accumulating layers,
in a state where a plurality of first conductive layers provided in a range from the first position in the stacking direction to a third position between the first position and the second position in the stacking direction, of the plurality of conductive layers, have been applied with a first voltage or with a second voltage greater than the first voltage, and
a plurality of second conductive layers provided in a range from the second position in the stacking direction to a fourth position between the second position and the third position in the stacking direction, of the plurality of conductive layers, have been applied with a third voltage greater than the first voltage and less than the second voltage, or with a fourth voltage greater than the third voltage,
one of the plurality of via electrodes is applied with a first program voltage.

10. The method of controlling the semiconductor memory device according to claim 9, wherein
at the first timing,
those corresponding to the part of the plurality of electric charge accumulating layers, of the plurality of first conductive layers are applied with the first voltage,
those not corresponding to the part of the plurality of electric charge accumulating layers, of the plurality of first conductive layers are applied with the second voltage,
those corresponding to the part of the plurality of electric charge accumulating layers, of the plurality of second conductive layers are applied with the third voltage, and
those not corresponding to the part of the plurality of electric charge accumulating layers, of the plurality of second conductive layers are applied with the fourth voltage.

11. The method of controlling the semiconductor memory device according to claim 9, wherein
the part of the plurality of electric charge accumulating layers includes an electric charge accumulating layer controlled to a second state from a first state, and
at the first timing,
those corresponding to the electric charge accumulating layers controlled to the second state, of the plurality of first conductive layers are applied with the first voltage,
others than those corresponding to the electric charge accumulating layers controlled to the second state, of the plurality of first conductive layers are applied with the second voltage,
those corresponding to the electric charge accumulating layers controlled to the second state, of the plurality of second conductive layers are applied with the third voltage, and
others than those corresponding to the electric charge accumulating layers controlled to the second state, of the plurality of second conductive layers are applied with the fourth voltage.

12. The method of controlling the semiconductor memory device according to claim 11, wherein
the part of the plurality of electric charge accumulating layers further includes an electric charge accumulating layer controlled to a third state from the first state, and
at a second timing of the program operation,
in a state where those corresponding to the electric charge accumulating layers controlled to the third state, of the plurality of first conductive layers have been applied with the first voltage,
others than those corresponding to the electric charge accumulating layers controlled to the third state, of the plurality of first conductive layers have been applied with the second voltage,
those corresponding to the electric charge accumulating layers controlled to the third state, of the plurality of second conductive layers have been applied with the third voltage, and
others than those corresponding to the electric charge accumulating layers controlled to the third state, of the plurality of second conductive layers have been applied with the fourth voltage,
the one of the plurality of via electrodes is applied with a second program voltage greater than the first program voltage.
